(19) United States
(12) Patent Application Publication
(10) Pub. No.: US 2023/0090408 A1
(43) Pub. Date: Mar. 23, 2023

(54) SEMICONDUCTOR DEVCIE AND MANUFACTURING METHOD FOR SEMICONDUCTOR DEVICE

(71) Applicant: FUJI ELECTRIC CO., LTD., Kawasaki-shi (JP)

(72) Inventor: Masashi HOYA, Shiojiri-city (JP)

(73) Assignee: FUJI ELECTRIC CO., LTD., Kawasaki-shi, Kanagawa (JP)

(21) Appl. No.: 17/872,738

(22) Filed: Jul. 25, 2022

(30) Foreign Application Priority Data
Sep. 21, 2021 (JP) 2021-153189

(51) Int. Cl. H01L 23/31; H01L 23/498; H01L 23/367

(52) U.S. Cl. CPC H01L 23/3114; H01L 23/49861; H01L 23/49833; H01L 23/3672; H01L 23/3135

(57) ABSTRACT

A semiconductor device includes a heatsink, an insulating resin layer on the heatsink, and a metallic plate including a first surface in contact with a first region of the insulating resin layer and a second surface to which a semiconductor chip is adhered. The device further includes a lead terminal connected to the metallic plate; a first mold resin covering a part of the metallic plate and a part of the lead terminal; and a second mold resin covering another part of the metallic plate, the semiconductor chip, and another part of the lead terminal. The first mold resin has a third surface in the same plane as that of the first surface, the third surface extending from an outer peripheral edge of the metallic plate to that of the insulating resin layer or outside thereof in plan view in contact with the second region of the insulating resin layer.

### CROSS REFERENCE TO RELATED APPLICATIONS

This application is based on, and claims priority from, Japanese Patent Application No. 2021-153189, filed Sep. 21, 2021, the entire contents of which are incorporated herein by reference.

### BACKGROUND

### Technical Field

The present disclosure relates to a semiconductor device and to a manufacturing method for a semiconductor device.

### Description of Related Art

The heat dissipation characteristics and the insulation characteristics of semiconductor devices that are used in power converters, such as a motor driving inverter and a DC-DC converter, have been conventionally improved. For example, Japanese Patent Application Laid-Open Publication No. 2005-123495, described below, discloses a manufacturing method for a semiconductor device including a resin molded chip. The manufacturing method for a semiconductor device in Japanese Patent Application Laid-Open Publication No. 2005-123495 includes a process of preparing a frame that includes a front side and a back side and that has a die pad, a process of preparing an insulating resin sheet that has a first surface and a second surface, a process of preparing a resin sealing mold that includes holding pins, a process of mounting the resin sheet inside of the resin sealing mold in such a manner that the second surface of the resin sheet is brought to contact with an internal bottom surface of the resin sealing mold, a process of mounting a power chip on a front side of the die pad, a process of arranging the frame on the first surface of the resin sheet in such a manner that a back side of the die pad is brought to contact with the first surface of the resin sheet, a process of holding the die pad against the resin sheet with the holding pins to fix the die pad, a process of filling a sealing resin in the resin sealing mold and curing the sealing resin, and a process of removing a semiconductor device from the resin sealing mold. In this manner, by bringing the insulating resin sheet having a high thermal conductivity into contact with the back side of the frame having the power chip mounted thereon and fixing the resin sheet, the resin sheet and the frame can be successfully firmly fixed to each other, and a semiconductor device having high heat dissipation characteristics and satisfactory insulation characteristics can be obtained.

In the conventional technique described above, heating and pressing are performed to cure the sealing resin in a state in which the frame having the die pad is arranged on the first surface of the resin sheet, and the die pad and the frame are held against the resin sheet with holding pins. At that time, the resin sheet is in a half-cured state, and there is a possibility that the resin sheet will deform due to pushing by the frame. Specifically, a part of the resin sheet located immediately below the outer peripheral edge of the frame is pushed outward with respect to the frame, so that bulges of the resin on the side surface of the frame and voids in the part of the resin sheet located immediately below the outer peripheral edge of the frame may be produced. The outer peripheral edge of the frame is a place at which the electric field is concentrated in a state in which the semiconductor device is operating. If an insulating resin layer in the vicinity includes a defect, there is a possibility that insulation breakdown of the insulating resin layer will occur, and reliability of the semiconductor device will be decreased.

### SUMMARY

In view of the above circumstances, one aspect of the present disclosure has an object of improving the reliability of a semiconductor device. In order to solve the above problems, a semiconductor device according to the present disclosure includes: a heatsink; an insulating resin layer, a surface of which includes a first region, and a second region different from the first region, the insulating resin layer being formed on the heatsink; a metallic plate including a first surface and a second surface opposite to the first surface, with the first surface in contact with the first region of the surface of the insulating resin layer; a first semiconductor chip adhered to the second surface; a first lead terminal connected to the metallic plate; a first mold resin covering a part of the metallic plate and a part of the first lead terminal; and a second mold resin formed of a resin material having a different property from that of the first mold resin, the second mold resin covering another part of the metallic plate, the first semiconductor chip, and another part of the first lead terminal, wherein the first mold resin includes a third surface located in the same plane as that of the first surface of the metallic plate, the third surface extending from an outer peripheral edge of the metallic plate to an outer peripheral edge of the insulating resin layer or outside thereof in plan view, and the third surface is in contact with the second region of the surface of the insulating resin layer.

A manufacturing method for a semiconductor device according to the present disclosure is a manufacturing method for the semiconductor described above, including: a process of covering a part of the metallic plate and a part of the first lead terminal with the first mold resin; a process of forming the insulating resin layer by bringing the first surface of the metallic plate and the third surface of the first mold resin into contact with a resin sheet and curing the resin sheet; and a process of covering the metallic plate, the first semiconductor chip, and a part of the first lead terminal with the second mold resin.

### BRIEF DESCRIPTION OF THE DRAWINGS

FIG. 1 is a circuit diagram illustrating a semiconductor device 10 according to an embodiment, and a peripheral configuration thereof;

FIG. 2A is a top view of an exterior of the semiconductor device 10;

FIG. 2B is a side view of the exterior of the semiconductor device 10;

FIG. 3 is an A-A sectional view of the semiconductor device 10;

FIG. 4A is a diagram with a part of a second mold resin 52 removed from the sectional view of FIG. 3;

FIG. 4B is a diagram in which first lead terminals 31 arranged inside of a first mold resin 51 in FIG. 4A are projected;

FIG. 5 is a sectional view of the semiconductor device along a Y direction;

FIG. 6 is a flowchart illustrating a manufacturing method for the semiconductor device 10;

FIG. 7 is a diagram illustrating a manufacturing process of the semiconductor device 10;

FIG. 8 is a diagram illustrating a manufacturing process of the semiconductor device 10;

FIG. 9 is a diagram illustrating a manufacturing process of the semiconductor device 10;

FIG. 10 is a diagram illustrating a manufacturing process of the semiconductor device 10;

FIG. 11 is a diagram illustrating a manufacturing process of the semiconductor device 10;

FIG. 12 is a diagram illustrating a manufacturing process of the semiconductor device 10;

FIG. 13 is a sectional view illustrating a modification of the semiconductor device 10;

FIG. 14A is a sectional view along an X direction of a semiconductor device 10A according to the modification;

FIG. 14B is a sectional view along the X direction of a semiconductor device 10B according to the modification; and

FIG. 15 is a diagram illustrating a configuration of a semiconductor device 100 according to a comparative example.

### DESCRIPTION OF THE EMBODIMENTS

Embodiments according to the present disclosure are explained with reference to the drawings. It is to be noted that the dimensions and scales of parts in the drawings are different from actual products, as appropriate. The embodiments described below are preferable specific examples of the present disclosure. Therefore, the following embodiments include various technically preferable limitations. However, the scope of the present disclosure is not limited to the embodiments unless it is so described in the following explanations that the present disclosure is specifically limited.

### First Embodiment

### A. Circuit Configuration of Semiconductor Device 10

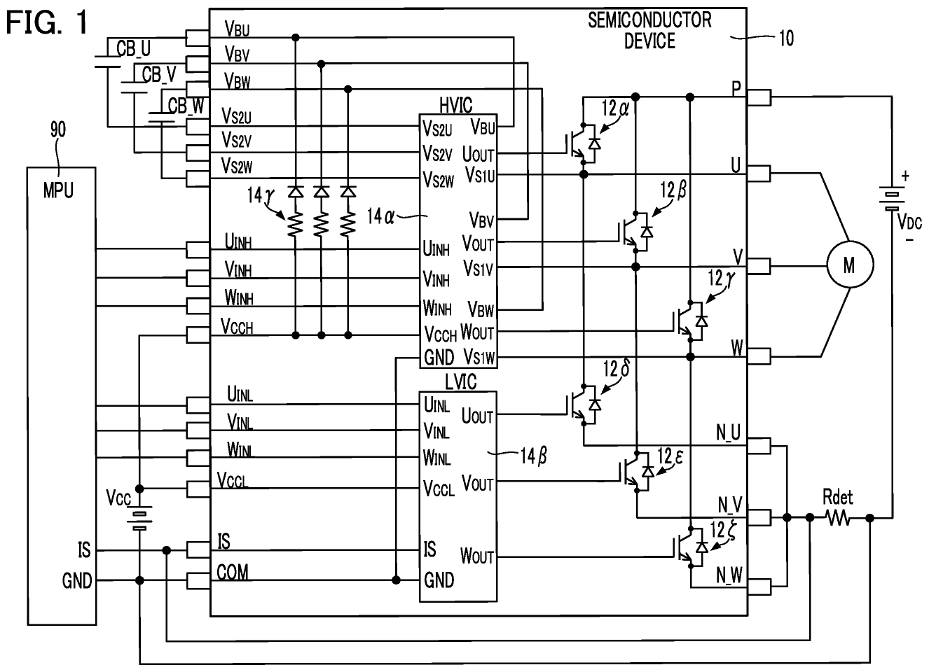

FIG. 1 is a circuit diagram illustrating a semiconductor device 10 according to an embodiment, and a peripheral configuration thereof. The semiconductor device 10 is a motor driving semiconductor device that drives a three-phase motor M. The semiconductor device 10 includes power semiconductor chips 12 and control semiconductor chips 14 (an HVIC 14α, an LVIC 14β, and BSDs 14γ). The power semiconductor chips 12 are an example of a first semiconductor chip and the control semiconductor chips 14 are an example of a second semiconductor chip.

In the present embodiment, the semiconductor device 10 includes six power semiconductor chips 12α to 12ξ The power semiconductor chips 12 are switching elements (IGBTs: Insulated Gate Bipolar Transistors) each having a high-voltage electrode (a collector), a low-voltage electrode (an emitter), and a control electrode (a gate), and reverse conducting switching elements (RC-IGBTs: Reverse Conducting-IGBTs) each having a rectifier element (a diode) having an anode electrode and a cathode electrode. In each of the power semiconductor chips 12, the high-voltage electrode of the switching element is connected to the cathode electrode of the rectifier element, and the low-voltage electrode of the switching element is connected to the anode electrode of the rectifier element.

Among the six power semiconductor chips 12α to 12ξ the power semiconductor chips 12α to 12γ constitute an upper arm and the power semiconductor chips 12δ to 12ξ constitute a lower arm. In the following descriptions, the power semiconductor chips 12α to 12γ are also referred to as “upper-arm semiconductor elements 12α to 12γ” and the power semiconductor chips 12δ to 12ξ are also referred to as “lower-arm semiconductor elements 12δ to 12ξ” The low-voltage electrodes of the upper-arm semiconductor elements 12α to 12γ and the high-voltage electrodes of the lower-arm semiconductor elements 12δ to 12ξ are connected with connecting lines and constitute series circuits, respectively.

The series circuits have output terminals U, V, and W connected to the connecting lines that respectively couple the upper-arm semiconductor elements 12α to 12γ and the lower-arm semiconductor elements 12δ to 12ξ, positive DC terminals P respectively connected to the high-voltage electrodes of the upper-arm semiconductor elements 12α to 12γ, and negative DC terminals N_U, N_V, and N_W respectively connected to the low-voltage electrodes of the lower-arm semiconductor elements 12δ to 12ξ, and constitute half-bridge circuits.

The semiconductor device 10 includes three half-bridge circuits (a U phase, a V phase, and a W phase). The positive DC terminals P of the half-bridge circuits are joined together inside the semiconductor device 10 to be connected to a positive voltage electrode of a DC power source VDC provided outside the semiconductor device 10. The negative DC terminals N_U, N_V, and N_W of the half-bridge circuits are joined together outside the semiconductor device 10 to be connected to a negative voltage electrode of the DC power source VDC via a current detecting resistor Rdet that is provided outside the semiconductor device 10. The semiconductor device 10 receives DC power from the DC power source VDC through the positive DC terminal P and the negative DC terminals N_U, N_V, and N_W. The output terminals U, V, and W are connected to input terminals U, V, and W of corresponding phases in the three-phase motor M, respectively, and the semiconductor device 10 supplies power required for driving of the three-phase motor M through the output terminals U, V, and W.

The semiconductor device 10 includes a high-side control IC (HVIC: High Voltage Integrated Circuit) 14α that controls driving states of the switching elements of the upper-arm semiconductor elements 12α to 12γ. Gate output terminals UOUT, VOUT, and WOUT of the HVIC 14α are connected to the control electrodes (gate electrodes) of the switching elements of the upper-arm semiconductor elements 12α to 12γ, respectively. First reference potential terminals VS1U, VS1V, and VS1 W of the HVIC 14α are connected to the low-voltage electrodes (emitters) of the switching elements of the upper-arm semiconductor elements 12α to 12γ, respectively. The HVIC 14α turns on or off the switching elements of the upper-arm semiconductor elements 12α to 12γ by changing voltages between the gate output terminals UOUT, VOUT, and WOUT and the first reference potential terminals VS1U, VS1V, and VS1 W, respectively.

Gate power supply terminals VBU, VBV, and VBW of the HVIC 14α are connected to one of the terminals of power supply capacitors CB_U, CB_V, and CB_W provided outside the semiconductor device 10, respectively. Second reference potential terminals VS2U, VS2V, and VS2 W of the HVIC 14α are connected to the other terminals of the power supply capacitors CB_U, CB_V, and CB_W, respectively. The HVIC 14α uses the power supply capacitors CB_U, CB_V, and CB_W as gate driving power sources for the switching elements of the upper-arm semiconductor elements 12α to 12γ, respectively.

Signal input terminals UINH, VINH, and WINH of the HVIC 14α are respectively connected to signal output terminals of an integrated operation unit (MPU; Micro Processing Unit) 90 provided outside the semiconductor device 10. A signal power supply terminal VCCH of the HVIC 14α is connected to a positive terminal of a signal power source Vcc provided outside the semiconductor device 10, and a ground terminal (GND) of the HVIC 14α is connected to a negative terminal of the signal power source VCC. Accordingly, the HVIC 14α receives PWM signals output from the signal output terminals of the MPU 90 at the signal input terminals UINH, VINH, and WINH, and transfers the signals to the gate output terminals UOUT, VOUT, and WOUT, respectively.

The semiconductor device 10 further includes boot strap diodes (BSDs) 14γ. In the present embodiment, the semiconductor device 10 includes three BSDs 14γ. The anodes of the BSDs 14γ are connected to the signal power supply terminal (VCCH) of the HVIC 14α. The cathodes of the BSDs 14γ are connected to one of the terminals of the power supply capacitors CB_U, CB_V, and CB_W, respectively. Accordingly, the BSDs 14γ charge the power supply capacitors CB_U, CB_V, and CB_W, respectively, using the signal power source VCC.

The semiconductor device 10 includes a low-side control IC (LVIC: Low Voltage Integrated Circuit) 14β that controls driving states of the switching elements of the lower-arm semiconductor elements 12δ to 12ξ. Gate output terminals UOUT, VOUT, and WOUT of the LVIC 14β are connected to the control electrodes (gate electrodes) of the switching elements of the lower-arm semiconductor elements 12δ to 12ξ respectively. A ground terminal GND of the LVIC 14β is connected to the negative DC terminals N_U, N_V, and N_W via the current detecting resistor Rdet, and the switching elements of the lower-arm semiconductor elements 12δ to 12ξ are turned on or off by changing voltages between the gate output terminals UOUT, VOUT, and WOUT and the ground terminal GND, respectively.

Signal input terminals UINL, VINL, and WINL of the LVIC 14β are connected to signal output terminals of the MPU 90, respectively. A signal power supply terminal VCCL of the LVIC 14β is connected to the positive terminal of the signal power source Vcc. The ground terminal GND of the LVIC 14β is also connected to the negative terminal of the signal power source VCC. Accordingly, the LVIC 14β receives PWM signals output from the signal output terminals of the MPU 90 at the signal input terminals UINL, VINL, and WINL of the LVIC 14β, and transfers the signals to the gate output terminals UOUT, VOUT, and WOUT, respectively.

The semiconductor device 10 has a function to detect currents flowing in the phases of the half-bridge circuits, respectively, using the current detecting resistor Rdet, and to protect the semiconductor device 10 from breakage at the time of overcurrent. A current level signal detected by the current detecting resistor Rdet is transmitted to the LVIC 14β via a current detection terminal IS. The LVIC 14β performs overcurrent determination on the basis of a reference value for the current and interrupts the currents of the switching elements of the lower-arm semiconductor elements 12δ to 12ξ when overcurrent occurs. In addition, protection of the switching elements of the upper-arm semiconductor elements 12α to 12γ is performed by the MPU 90. The current level signal detected by the current detecting resistor Rdet is transmitted also to the MPU 90. The MPU 90 performs overcurrent determination on the basis of the reference value and interrupts the currents of the switching elements of the upper-arm semiconductor elements 12α to 12γ to protect the semiconductor device 10 when overcurrent occurs.

### B. Configuration of Semiconductor Device 10

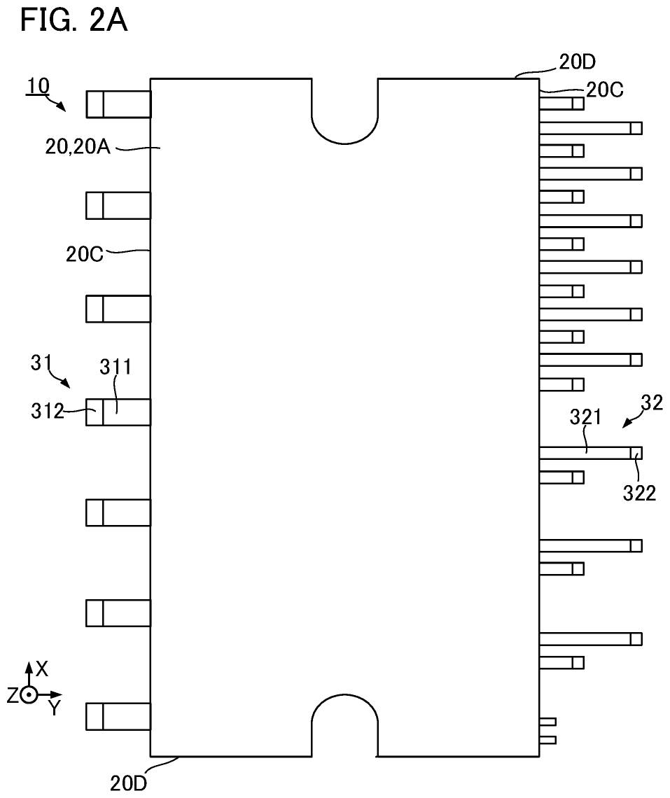

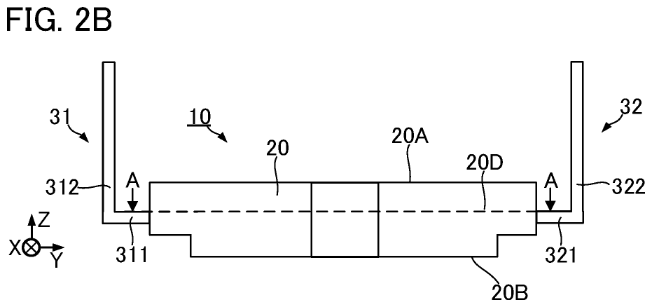

FIG. 2A is a top view of an exterior of the semiconductor device 10, and FIG. 2B is a side view of the exterior of the semiconductor device 10. The semiconductor device 10 includes a main body portion 20 and a plurality of lead terminals (first lead terminals 31 and second lead terminals 32). The lead terminals are exposed from the main body portion 20. The main body portion 20 includes a top surface 20A, a bottom surface 20B, a pair of side surfaces 20C, and a pair of side surfaces 20D. The top surface 20A and the bottom surface 20B have a substantially rectangular shape. The long sides of the top surface 20A and the long sides of the bottom surface 20B are the same in length. However, the short sides of the top surface 20A and the short sides of the bottom surface 20B are different in length, and the short sides of the bottom surface 20B are shorter. The side surfaces 20C connect the long sides of the top surface 20A and the long sides of the bottom surface 20B to each other. Since the short sides of the top surface 20A and the short sides of the bottom surface 20B are different in length as described above, the side surfaces 20C have a step. The side surfaces 20D connect the short sides of the top surface 20A and the short sides of the bottom surface 20B to each other.

In the following descriptions, XYZ coordinates are assumed in a space in which the semiconductor device 10 is placed. The long sides of the top surface 20A and the bottom surface 20B extend along an X direction. The short sides of the top surface 20A and the bottom surface 20B extend along a Y direction. The top surface 20A and the bottom surface 20B are spaced apart from each other along the Z direction. That is, the Z direction is a height direction of the semiconductor device 10.

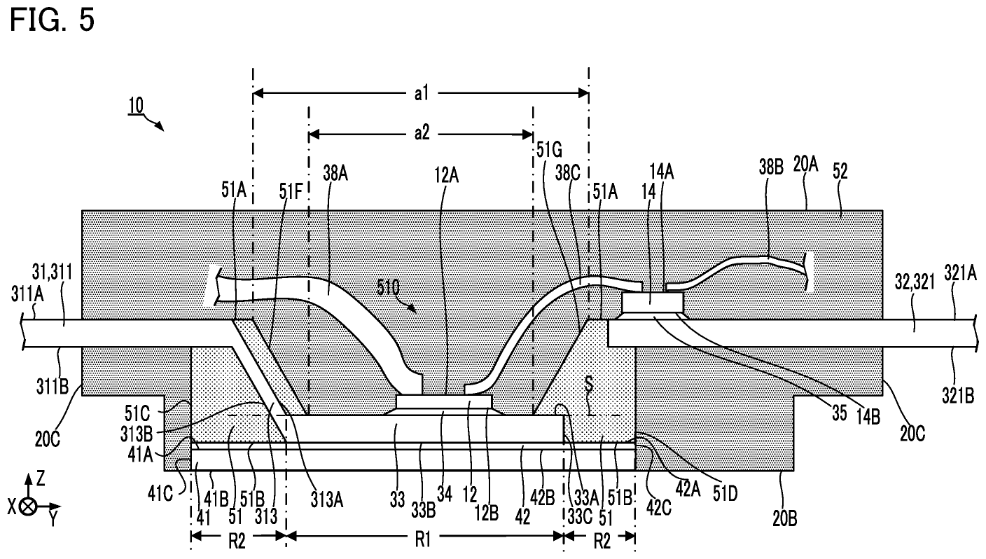

Among the surfaces of the main body portion 20, the top surface 20A, the side surfaces 20C, and the side surfaces 20D are entirely formed of a second mold resin 52, which will be described later. A central part of the bottom surface 20B is formed of a bottom surface 41B of a heatsink 41 (see FIG. 5), which will be described later, and a peripheral portion of the central part is formed of the second mold resin 52.

A plurality of first lead terminals 31 and a plurality of second lead terminals 32 are exposed to an outside of the main body portion 20 from the side surfaces 20C, respectively. The first lead terminals 31 each include an outer lead portion 311 extending in the Y direction from the associated side surface 20C, and a tip portion 312 erected upward from the tip of the outer lead portion 311. The second lead terminals 32 each include an outer lead portion 321 extending in the Y direction from the associated side surface 20C, and a tip portion 322 erected upward from the tip of the outer lead portion 321.

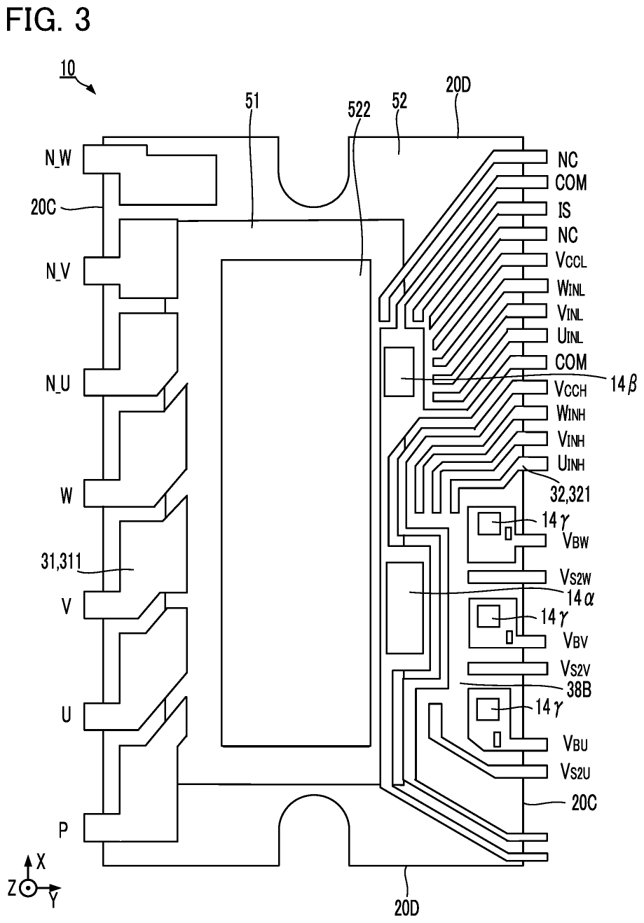

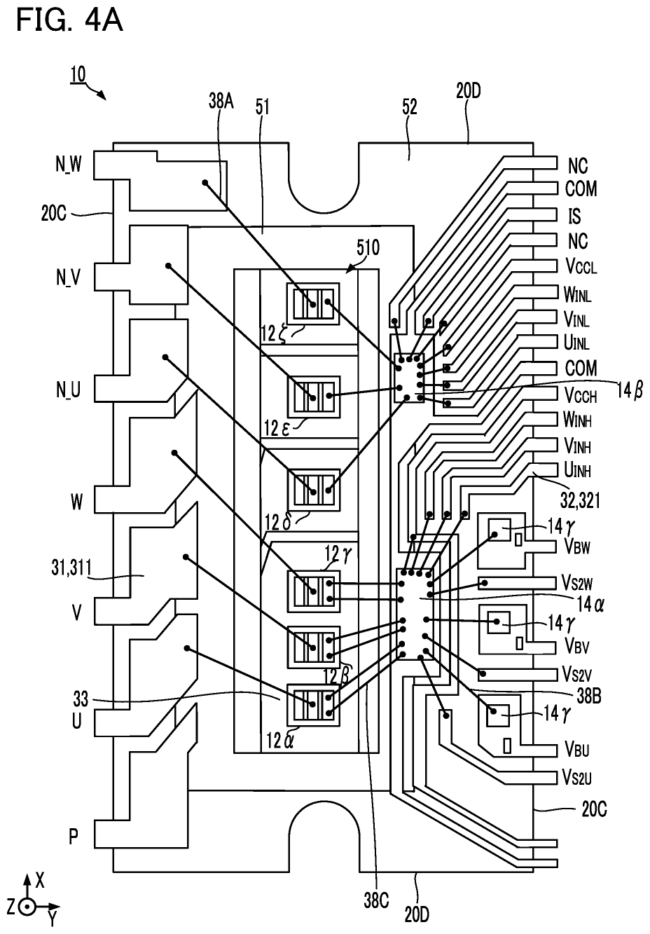

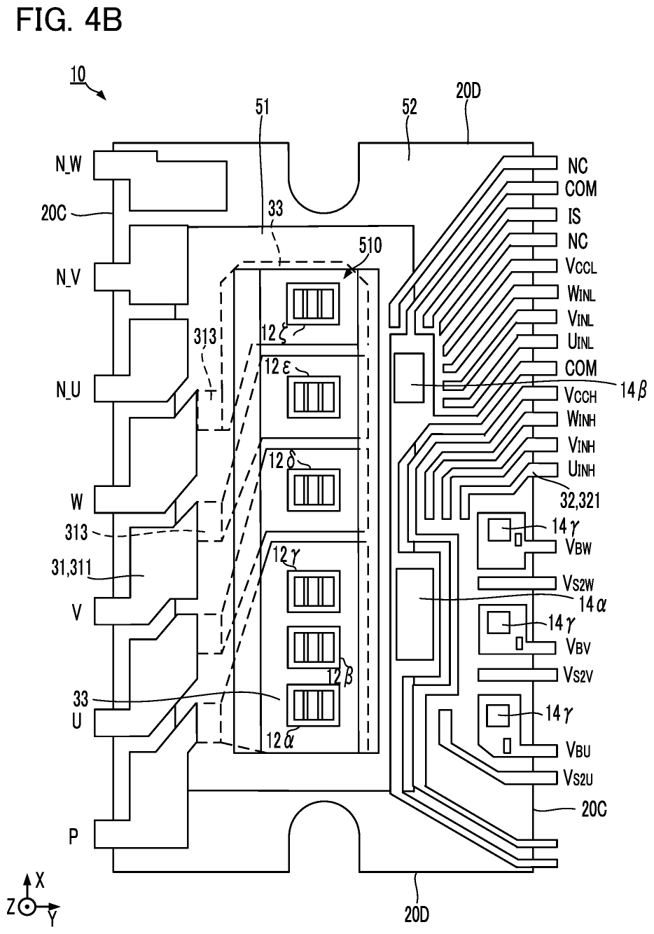

FIG. 3 is an A-A sectional view of the semiconductor device 10. FIG. 4A is a diagram with a part of the second mold resin 52 (a second mold resin 522 in an opening 510 described later) removed from the sectional view of FIG. 3. FIG. 4B is a diagram in which the first lead terminals 31 arranged inside of a first mold resin 51 in FIG. 4A are projected. Wires 38 are illustrated in FIG. 4A, whereas illustrations of the wire 38 are omitted in FIG. 4B in order to facilitate illustration. The designations of the lead terminals (the first lead terminals 31 and the second lead terminals 32) illustrated in FIG. 4A correspond to designations of the terminals illustrated in FIG. 1. FIG. 5 is a sectional view of the semiconductor device 10 along the Y direction. FIG. 5 schematically illustrates an arrangement of members constituting the semiconductor device 10 along the Y direction. Illustrations of the tip portions 312 of the first lead terminals 31 and the tip portions 322 of the second lead terminals 32 are omitted in FIGS. 3 to 5.

As shown in FIG. 5, the semiconductor device 10 includes the heatsink 41, an insulating resin layer 42, metallic plates 33, the first lead terminals 31, the second lead terminals 32, the wires 38, the power semiconductor chips 12, the control semiconductor chips 14, the first mold resin 51, and the second mold resin 52.

The heatsink 41 is a rectangular flat plate (metallic plate) made of metal and has top surface 41A, bottom surface 41B, and side surface 41C. The bottom surface 41B is a surface on a side opposite the top surface 41A. The side surface 41C connects the top surface 41A and the bottom surface 41B to each other. The side surface 41C of the heatsink 41 is an example of an outer peripheral surface of the heatsink 41. The heatsink 41 protects the insulating resin layer 42 and releases heat produced by driving of the power semiconductor chips 12 to outside the semiconductor device 10. As described above, the bottom surface 41B of the heatsink 41 constitutes the bottom surface 20B of the semiconductor device 10. In the present embodiment, the bottom surface 41B of the heatsink 41 and the second mold resin 52 are located in the same plane in the bottom surface 20B of the semiconductor device 10.

In the present embodiment, “being in the same plane” includes a case of being located in substantially the same plane, as well as a case of being located completely in the same plane. “A surface a and a surface b are located in substantially the same plane” indicates, for example, a case in which a difference in the level between the surface a and the surface b is within a range of manufacturing error. Specifically, when there is a difference in the level caused by a dimension error within a range of ±10% (more preferably ±5%) between the surface a and the surface b, the surface a and the surface b are regarded as “being continuous with no step.” A configuration of the surface a and the surface b being continuous with no step has an advantage that damage resulting from stress concentration or insufficient stiffness at a stepped portion can be suppressed. In other words, when in a range that can realize an effect of suppression of damage exemplified above, the surface a and the surface b can be regarded as “being in the same plane” even if there is actually a step therebetween.

The insulating resin layer 42 is made of an insulating resin and insulates the metallic plates 33 being a part of an internal circuit of the semiconductor device 10 from the heatsink 41 that is exposed to the outside of the semiconductor device 10. The insulating resin layer 42 includes a top surface 42A, a bottom surface 42B, and a side surface 42C. The bottom surface 42B is a surface on a side opposite the top surface 42A. The side surface 42C connects the top surface 42A and the bottom surface 42B to each other. The top surface 42A of the insulating resin layer 42 is an example of the surface of the insulating resin layer 42. The side surface 42C of the insulating resin layer 42 is an example of an outer peripheral surface of the insulating resin layer 42. The bottom surface 42B of the insulating resin layer 42 is formed on the top surface 41A of the heatsink 41. The outer peripheral edges of the insulating resin layer 42 and the heatsink 41 are aligned in plan view. That is, the side surface 42C of the insulating resin layer 42 and the side surface 41C of the heatsink 41 are located in the same plane. In the present embodiment, the plan view is a view of the semiconductor device 10 mounted on an XY plane from the Z direction. A planar shape indicates a shape in plan view.

The metallic plates 33 are plates made of metal and each include a top surface 33A, a bottom surface 33B, and a side surface 33C. The bottom surface 33B is a surface on a side opposite the top surface 33A. The side surface 33C connects the top surface 33A and the bottom surface 33B to each other. The top surface 33A of each of the metallic plates 33 is an example of a second surface and the bottom surface 33B of each of the metallic plates 33 is an example of a first surface. The side surface 33C of each of the metallic plates 33 is an example of an outer peripheral surface of the metallic plate 33. The bottom surfaces 33B of the metallic plates 33 are arranged on the top surface 42A of the insulating resin layer 42. The bottom surfaces 33B of the metallic plates 33 are in contact with a part of the top surface 42A of the insulating resin layer 42.

A region in contact with the bottom surfaces 33B of the metallic plates 33 in the top surface 42A of the insulating resin layer 42 is a first region R1. A region other than the first region R1 in the top surface 42A of the insulating resin layer 42 is a second region R2. A plane along the top surfaces 33A of the metallic plates 33 is a reference plane S. The reference plane S is an example of a plane including the top surfaces 33A of the metallic plates 33.

The first lead terminals 31 and the second lead terminals 32 supply power or a signal from outside to the power semiconductor chips 12 and the control semiconductor chips 14 in the semiconductor device 10. Inside the semiconductor device 10, the first lead terminals 31 are each formed in a single piece with a corresponding metallic plate 33 to which the power semiconductor chip 12 is adhered. In addition, the second lead terminals 32 are provided separately from the metallic plates 33.

Each of the first lead terminals 31 includes an inner lead portion 313 connected to, of the ends of the outer lead portion 311, an end opposite the tip portion 312, as well as the outer lead portion 311 and the tip portion 312 described above (see FIG. 2A and the like). The outer lead portion 311 is an example of a first portion and the inner lead portion 313 is an example of a second portion. A part of the outer lead portion 311 is exposed from the main body portion 20 (the second mold resin 52) of the semiconductor device 10 and is connected to the tip portion 312. The inner lead portion 313 connects the outer lead portion 311 and the associated metallic plate 33 to each other. That is, the first lead terminals 31 are connected to the metallic plates 33.

The outer lead portions 311 are positioned in a substantially central part of the main body portion 20 in the Z direction and the metallic plates 33 are positioned in a lower part of the semiconductor device 10 in the Z direction. That is, the outer lead portions 311 and the metallic plates 33 are away from each other in the Z direction. The locations of end portions of the outer lead portions 311 adjacent to the inner lead portions 313 and the locations of end portions of the metallic plates 33 adjacent to the inner lead portions 313 are not aligned in the Y direction in plan view. Therefore, the inner lead portions 313 extend in the Z direction while being inclined with respect to the XY plane.

The outer lead portions 311 each have a top surface 311A, and a bottom surface 311B on a side opposite the top surface 311A. A section line A-A illustrated in FIG. 2B is along the top surfaces 311A of the outer lead portions 311. The inner lead portions 313 each have a top surface 313A, and a bottom surface 313B on a side opposite to the top surface 313A.

Each of the second lead terminals 32 includes the outer lead portion 321 and the tip portion 322 as described above. A part of the outer lead portion 321 is exposed from the main body portion 20 (the second mold resin 52) of the semiconductor device 10 and is connected to the tip portion 322. As illustrated in FIG. 5, the outer lead portions 321 are positioned in a substantially central part of the main body portion 20 in the Z direction and are provided away from the metallic plates 33 in the Z direction. The second lead terminals 32 are also made of a thin plate of the same metal as that of the metallic plates 33. The outer lead portions 321 each have a top surface 321A, and a bottom surface 321B on a side opposite to the top surface 321A. The locations of the top surfaces 311A of the outer lead portions 311 in the Z direction and the height of the top surfaces 321A of the outer lead portions 321 are the same.

Each of the power semiconductor chips 12 has a top surface 12A, a bottom surface 12B, and a side surface 12C. The bottom surface 12B is located on the opposite side to the top surface 12A. The side surface 12C connects the top surface 12A and the bottom surface 12B to each other. The bottom surface 12B of each of the power semiconductor chips 12 is adhered to the top surface 33A of the associated metallic plate 33 with an adhesion material 34 such as solder. The low-voltage electrodes (emitters) and the control electrodes (gates) of the switching elements, and the anode electrodes of the rectifier elements, are arranged on the top surfaces 12A of the power semiconductor chips 12. The high-voltage electrodes (collectors) of the switching elements, and the cathode electrodes of the rectifier elements are arranged on the bottom surfaces 12B. Power wires 38A and interelement wires 38C are connected to the top surfaces 12A of the power semiconductor chips 12.

Each of the control semiconductor chips 14 has a top surface 14A, a bottom surface 14B, and a side surface 14C. The bottom surface 14B is located on the side opposite to the top surface 14A. The side surface 14C connects the top surface 14A and the bottom surface 14B to each other. The bottom surface 14B of each of the control semiconductor chips 14 is adhered to the top surface 321A of the associated outer lead portion 321 with an adhesion material 35 such as a conductive or insulating adhesive. Control wires 38B and the interelement wires 38C are connected to the top surfaces 14A of the control semiconductor chips 14.

The wires 38 connect the first lead terminals 31, the second lead terminals 32, the power semiconductor chips 12, and the control semiconductor chips 14 with each other. Wires connecting the first lead terminals 31 to the power semiconductor chips 12 are the power wires 38A, wires connecting the second lead terminals 32 to the control semiconductor chips 14 are the control wires 38B, and wires connecting the power semiconductor chips 12 to the control semiconductor chips 14 are the interelement wires 38C.

The first mold resin 51 has a top surface 51A, a bottom surface 51B, a side surface 51C, and a side surface 51D, as illustrated in FIGS. 4B and 5. The bottom surface 51B is located on the opposite side to the top surface 51A. Each of the side surface 51C and the side surface 51D connects the top surface 51A and the bottom surface 51B to each other. The side surface 51C is a surface located adjacent to the first lead terminals 31 and the side surface 51D is a surface located adjacent to the second lead terminals 32. The top surface 51A is an example of a fourth surface, the bottom surface 51B is an example of a third surface, and the side surfaces 51C and 51D are an example of a fifth surface.

The top surface 51A of the first mold resin 51 is located in the same plane as the top surfaces 311A of the outer lead portions 311 of the first lead terminals 31 and the top surface 321A of the outer lead portions 321 of the second lead terminals 32.

The bottom surface 51B of the first mold resin 51 is located in the same plane as the bottom surfaces 33B of the metallic plates 33. The location of the outer edge of the first mold resin 51, that is, the side surface 51C and the side surface 51D in plan view is aligned with the location of the outer edge of the heatsink 41 and the outer edge of the insulating resin layer 42 (the location of the side surface 41C and the side surface 42C in plan view). The outer edge of the first mold resin 51 may be located outer than the location of the outer edges of the heatsink 41 and the insulating resin layer 42. Also in this case, it is preferable that the side surfaces 51C and 51D of the first mold resin 51 be covered by the second mold resin 52.

As shown in FIG. 4B, an opening 510 extending from the top surface 51A to the bottom surface 51B is formed in a central part of the first mold resin 51 in plan view. Adjacent to the bottom surface 51B in the opening 510, there is exposed, of the top surface 33A of the metallic plates 33, at least a part at which the power semiconductor chip 12 is arranged. The metallic plates 33 are exposed in the opening 510 and the power semiconductor chips 12 are arranged on the metallic plates 33. As a result of formation of the opening 510, the planar shape of the first mold resin 51 is a rectangular frame shape.

The opening 510 is a space surrounded by the inner peripheral surface of the first mold resin 51. The inner peripheral surface of the first mold resin 51 includes wall surfaces 51F and 51G. The wall surfaces 51F and 51G are flat surfaces connecting the top surface 51A and the bottom surface 51B to each other. The wall surface 51F is a surface adjacent to the first lead terminals 31 and the wall surface 51G is a surface adjacent to the second lead terminals 32.

The wall surface 51F covers the top surfaces 313A of the inner lead portions 313 and are inclined with respect to the XY plane at substantially the same angle as that of the inner lead portions 313. The wall surface 51G is inclined with respect to the XY plane at substantially the same angle as that of the wall surface 51F. The inclination direction of the wall surface 51F is opposite to that of the wall surface 51G and the sectional area of the opening 510 on the XY plane increases as approaching from the bottom surface 51B to the top surface 51A.

The second mold resin 52 forms the main body portion 20 of the semiconductor device 10. The second mold resin 52 forms the top surface 20A, the bottom surface 20B, and the side surfaces 20C and 20D illustrated in FIGS. 2A, 2B, and 5.

The first mold resin 51 and the second mold resin 52 are formed of resin materials having different properties. The different properties include a case in which the types of the resin materials are different and also a case in which the materials are of the same type, but are different in the composition (for example, the filler amount). In the present embodiment, the thermal conductivity of the first mold resin 51 is higher than that of the second mold resin 52. Specifically, for example, a high thermal conductivity mold resin having a thermal conductivity equal to or greater than 2 W/Km is used as the first mold resin 51 and a general mold resin having a thermal conductivity lower than 1 W/Km is used as the second mold resin 52.

The thermal expansion coefficient of the first mold resin 51 may be equal to that of the second mold resin 52, whereas the thermal conductivity of the first mold resin 51 is greater than that of the second mold resin 52. It is sufficient in the present embodiment for thermal expansion coefficients being “equal” to be thermal expansion coefficients that are substantially equal including a range of manufacturing error. Specifically, when the thermal expansion coefficients are in a range of ±10% (more preferably ±5%), these thermal expansion coefficients are regarded as being equal.

For example, in the first mold resin 51 and the second mold resin 52, a thermosetting resin such as an epoxy resin is used as a primary material, and silica, alumina, boron nitride, or the like is added as filler. For example, the first mold resin 51 and the second mold resin 52 can be the same epoxy resin having different fillers, respectively. With use of the same epoxy resin, adhesion between the first mold resin 51 and the second mold resin 52 is increased, and breakage of the semiconductor device 10 caused by separation or the like can be avoided. In this case, the ratio of the filler included in the first mold resin 51 can be greater than the ratio of the filler included in the second mold resin 52. This easily enables the thermal conductivity of the first mold resin 51 to be greater than that of the second mold resin 52. Alternatively, the ratio of the boron nitride filler included in the first mold resin 51 can be greater than that of the boron nitride filler included in the second mold resin 52. No boron nitride filler may be included in the second mold resin 52, whereas the boron nitride filler is included in the first mold resin 51. This easily enables the thermal expansion coefficient of the first mold resin 51 to be equal to that of the second mold resin 52 while setting the thermal conductivity of the first mold resin 51 to be greater than that of the second mold resin 52.

### C. Manufacturing Method for Semiconductor Device 10

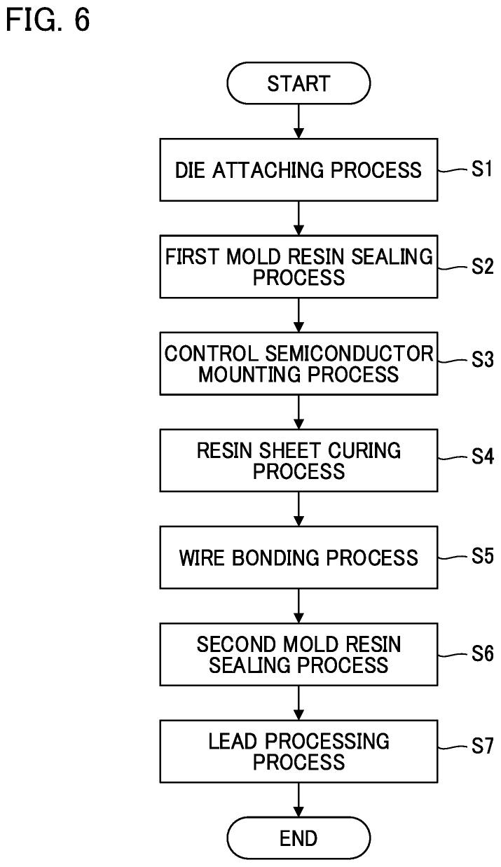

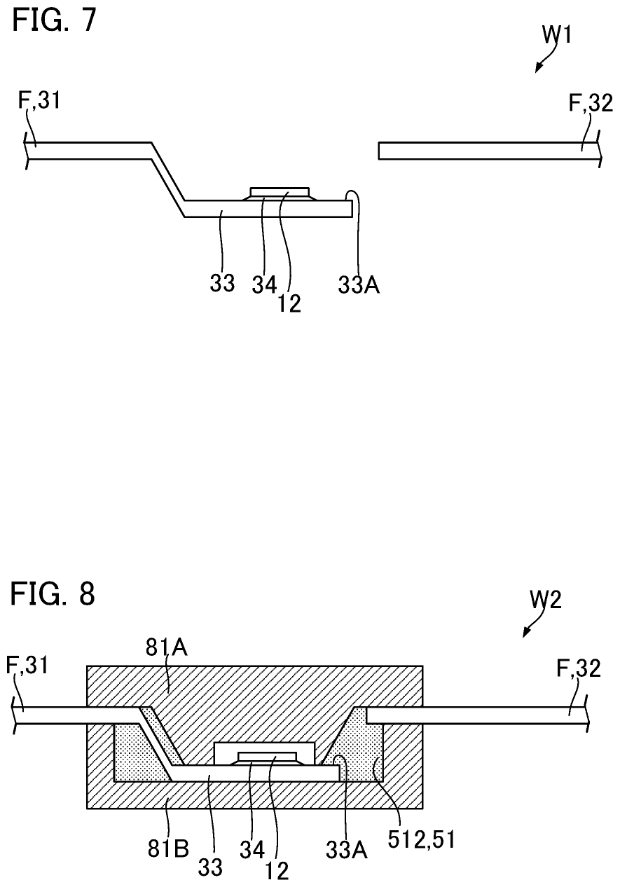

A manufacturing method for the semiconductor device 10 is explained next with reference to FIGS. 6 to 12. FIG. 6 is a flowchart illustrating a manufacturing method for the semiconductor device 10. First, a lead frame F including the metallic plates 33, the first lead terminals 31, and the second lead terminals 32 as one unit is prepared as illustrated in FIG. 7. A workpiece W1 is created by adhering the power semiconductor chips 12 onto the top surfaces 33A of the metallic plates 33 with the adhesion material 34 (Step S1: die attaching process).

Next, as illustrated in FIG. 8, a workpiece W2 is formed by forming the first mold resin 51 on the workpiece W1 (Step S2: first mold resin sealing process). Specifically, the workpiece W1 is first placed in a mold cavity 81 for the first mold resin 51. The mold cavity 81 is composed of an upper mold 81A and a lower mold 81B. Next, a liquid resin material 512, to be the first mold resin 51, is filled in the mold cavity 81. The first mold resin 51 is formed by curing the resin material 512, so that the workpiece W2 is completed.

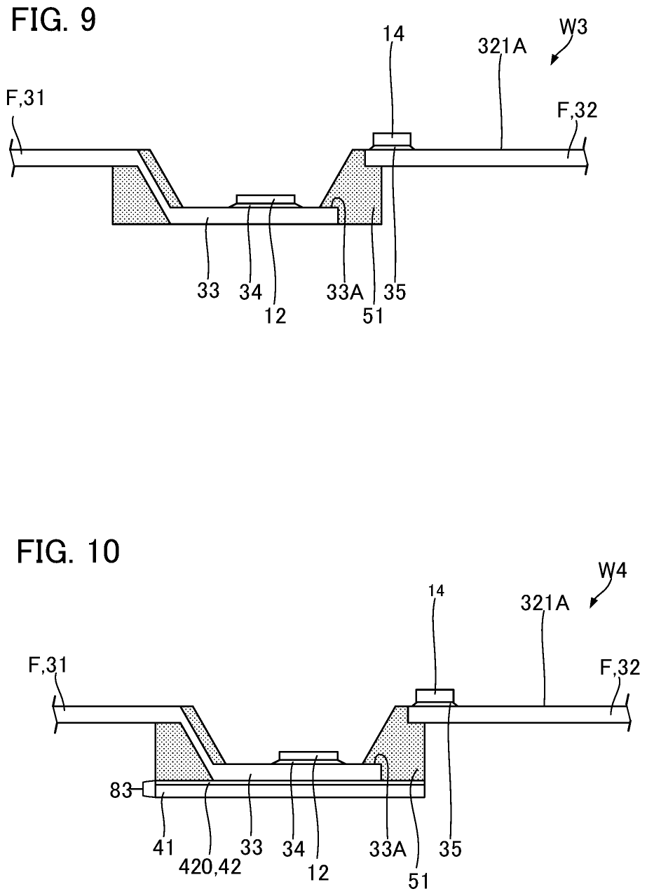

Subsequently, as illustrated in FIG. 9, the workpiece W2 is removed from the mold cavity 81 and the control semiconductor chips 14 are adhered to the top surfaces 321A of the outer lead portions 311 of the associated second lead terminals 32 with the adhesion material 35 (an insulating or conducting adhesive) to create a workpiece W3 (Step S3: control semiconductor mounting process). The order of Steps S1 to S3 may be changed.

Next, as illustrated in FIG. 10, a plate-like member 83 having a resin sheet 420 stacked on the top surface 41A of the heatsink 41 is prepared. The resin sheet 420 is in a half-cured state (B stage). The workpiece W3 is mounted on the plate-like member 83 in such a manner that the bottom surfaces 33B of the metallic plates 33 and the bottom surface 51B of the first mold resin 51 are brought into contact with a surface of the plate-like member 83 adjacent to the resin sheet 420 (a surface corresponding to the top surface 42A of the insulating resin layer 42), and are held for a certain time while being pressurized and heated. Accordingly, the resin sheet 420 is cured to become the insulating resin layer 42, and a workpiece W4 in which the workpiece W3, the insulating resin layer 42, and the heatsink 41 are fixed, is created (Step S4: resin sheet curing process).

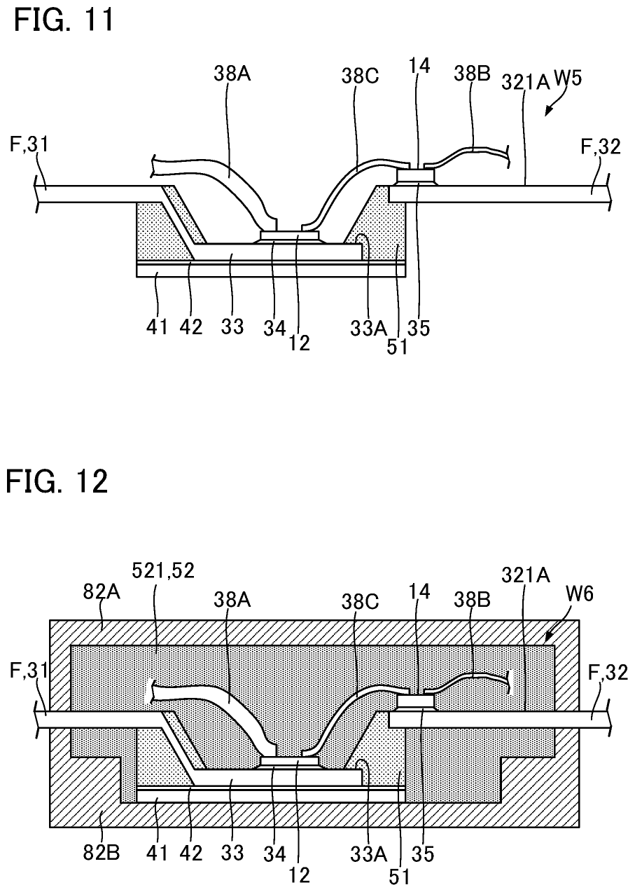

Subsequently, as illustrated in FIG. 11, the power semiconductor chips 12, the control semiconductor chips 14, the first lead terminals 31, and the second lead terminals 32 of the workpiece W4 are mutually connected with the wires 38 (38A, 38B, and 38C) to create a workpiece W5 (Step S5: wire bonding process).

Next, as illustrated in FIG. 12, a workpiece W6 is formed by forming the second mold resin 52 on the workpiece W5 (Step S6: second mold resin sealing process). Specifically, the workpiece W5 is first placed in a mold cavity 82 for the second mold resin 52. The mold cavity 82 is composed of an upper mold 82A and a lower mold 82B. Next, a liquid resin material 521, being the second mold resin 52, is filled in the mold cavity 82. The second mold resin 52 is formed by curing the resin material 521, so that the workpiece W6 is completed.

Finally, the workpiece W6 is removed from the mold cavity 82, and tie bars of the first lead terminals 31 and the second lead terminals 32 unified in the lead frame F are cut to separate the first lead terminals 31 and the second lead terminals 32 (Step S7: lead processing process). The semiconductor device 10 is completed through the processes described above.

### D. Comparative Example

FIG. 15 is a diagram illustrating a configuration of a semiconductor device 100 according to a comparative example. In the configurations of the semiconductor device 100, configurations identical to those of the semiconductor device 10 according to the embodiment are denoted by like reference signs and detailed descriptions thereof are omitted.

In the semiconductor device 100, the first mold resin 51 is not provided and the second mold resin 52 is arranged also in a part in which the first mold resin 51 is provided in the semiconductor device 10. Therefore, in the resin sheet curing process illustrated at Step S4 in FIG. 6, only the bottom surfaces 33B of the metallic plates 33 are in contact with the resin sheet constituting the insulating resin layer 42.

When the metallic plates 33 are pressed against the resin sheet in this state, pressing force is concentrated on parts of the resin sheet being in contact with outer peripheral edges 33E of the bottom surfaces 33B of the metallic plates 33, and there is a possibility that these parts will be deformed. Specifically, parts of the resin sheet located immediately below the outer peripheral edges 33E are pushed outward with respect to the metallic plates 33, so that bulges of the resin on the side surfaces of the metallic plates 33 and voids in the parts of the resin sheet located immediately below the outer peripheral edges 33E may be produced. The outer peripheral edges 33E of the metallic plates 33 are places at which the electric field is concentrated in a state in which the semiconductor device 100 is operating. If the insulating resin layer 42 in the vicinity has a defect, there is a possibility that insulation breakage of the insulating resin layer 42 will be caused, and reliability of the semiconductor device 100 will be decreased.

### E. Characteristics of First Mold Resin 51

The semiconductor device 10 according to the embodiment is characterized in including the first mold resin 51 that differs in a property from the second mold resin 52 that covers the external surface of the semiconductor device 10 as compared with the semiconductor device 100 according to the comparative example illustrated in FIG. 15. Characteristics in the location relationship between the first mold resin 51 and other constituent portions are explained more specifically below.

### First Characteristic

The bottom surface 51B of the first mold resin 51 and the bottom surfaces 33B of the metallic plates 33 are located in the same plane. As illustrated in FIG. 5, the first mold resin 51 is mainly arranged around the metallic plates 33 and covers a part of the metallic plates 33 and a part of the first lead terminals 31. The bottom surface 51B of the first mold resin 51 and the bottom surfaces 33B of the metallic plates 33 are located in the same plane. Since the outer edge of the first mold resin 51 is aligned with the outer edge of the insulating resin layer 42, the top surface 42A of the insulating resin layer 42 is entirely covered by the bottom surface 51B of the first mold resin 51 or the bottom surfaces 33B of the metallic plates 33.

That is, the first mold resin 51 covers a part of the metallic plates 33 and a part of the first lead terminals 31. The first mold resin 51 includes the bottom surface 51B located in the same plane as that of the bottom surfaces 33B of the metallic plates 33 extending from the outer peripheral edges of the metallic plates 33 to the outer peripheral edge of the insulating resin layer 42 or outside thereof in plan view. The bottom surface 51B is in contact with the second region R2, which differs from the first region R1 of the surface of the insulating resin layer 42.

According to a first characteristic, a part of the metallic plates 33 is covered by the first mold resin 51 and the bottom surfaces 33B of the metallic plates 33 and the bottom surface 51B of the first mold resin 51 are in the same plane. Therefore, when the metallic plates 33 are brought into contact with the insulating resin layer 42, the bottom surface 51B of the first mold resin 51 in addition to the bottom surfaces 33B of the metallic plates 33 is brought to contact with the top surface 42A of the insulating resin layer 42. Accordingly, compared to a case in which only the metallic plates 33 are brought into contact with the insulating resin layer 42 as in the comparative example, the contact area between the insulating resin layer 42 and other members (the metallic plates 33 and the first mold resin 51) is increased. At the time of forming the insulating resin layer 42 by curing the resin sheet 420 as indicated at Step S4 (the resin sheet curing process) in FIG. 6, the workpiece W3 is mounted in such a manner that the bottom surfaces 33B of the metallic plates 33 and the bottom surface 51B of the first mold resin 51 are brought into contact with the resin sheet 420, and they are held for a certain time while being pressurized and heated (see FIG. 10). Due to an increase in the contact area between the resin sheet 420 and the workpiece W3, the pressing force of the workpiece W3 that presses the resin sheet 420 is distributed, and local concentration of stress is suppressed. Therefore, local deformation of the resin sheet 420 can be suppressed.

In particular, if end portions of the metallic plates 33 are brought into contact with the resin sheet 420 as in the comparative example, the pressing force is concentrated on parts of the resin sheet 420 being in contact with the end portions, and these parts may be deformed. In the semiconductor device 10, the bottom surface 51B of the first mold resin 51 located in the same plane as that of the bottom surfaces 33B of the metallic plates 33 extends to a location overlapping with the line of the outer peripheral edge of the insulating resin layer 42 (the resin sheet 420). Therefore, the end portions of the metallic plates 33 are not positioned on the resin sheet 420, and deformation of the resin sheet 420 during curing can be prevented.

The outer peripheral edges of the metallic plates 33 are places at which the electric field is concentrated in a state in which the semiconductor device 10 is operating. If the insulating resin layer 42 in the vicinity of these places has a defect, there is a possibility that insulation breakage of the insulating resin layer 42 will be caused and reliability of the semiconductor device will be decreased. According to the first characteristic, defects in the insulating resin layer 42 in the vicinity of the outer peripheral edges of the metallic plates 33 can be suppressed, and the reliability of the semiconductor device 10 can be improved.

### Second Characteristic

The top surface 51A of the first mold resin 51 is parallel to the bottom surface 51B thereof. As illustrated in FIG. 5, the first mold resin 51 includes the top surface 51A on a side opposite to the bottom surface 51B, and the top surface 51A is parallel to the bottom surface 51B. The top surface 51A of the first mold resin 51 is in the same plane as that of the top surfaces 311A of the outer lead portions 311 in the example of FIG. 5. In a second characteristic, however the top surface 51A may be, for example, at a location lower than the bottom surfaces 311B of the outer lead portions 311. Alternatively, the top surface 51A may be, for example, at a location higher than the top surfaces 311A of the outer lead portions 311, and the outer lead portions 311 may be covered by the first mold resin 51.

According to the second characteristic, the first mold resin 51 has the top surface 51A parallel to the bottom surface 51B of the first mold resin 51 that is in contact with the insulating resin layer 42. Therefore, when the pressing force is planarly applied from the top surface 51A of the first mold resin 51 in the resin sheet curing process (Step S4 in FIG. 6), the pressing force is uniformly transmitted to the resin sheet 420 and local concentration of stress is suppressed. Accordingly, deformation of the resin sheet 420 can be suppressed.

### Third Characteristic

The top surface 51A of the first mold resin 51 is in the same plane as that of the top surfaces 311A of the outer lead portions 311 of the first lead terminals 31. As illustrated in FIG. 5, the top surface 51A of the first mold resin 51 is in the same plane as that of the top surfaces 311A of the outer lead portions 311 of the first lead terminals 31. That is, the first lead terminals 31 each include the outer lead portion 311 that extends in parallel to the reference plane S including the top surfaces 33A of the metallic plates 33, the outer lead portion 311 being spaced apart from the reference plane S such that the reference plane S is between the outer lead portion 311 and the insulating resin layer 42. Also, the first lead terminals 31 each include the inner lead portion 313 joining the outer lead portion 311 and the associated metallic plate 33 together. The top surface 51A of the first mold resin 51 is located in the same plane as that of the top surfaces 311A of the outer lead portions 311 not facing the reference plane S, the top surfaces 311A being on the opposite side of the bottom surfaces 311B facing the reference plane S.

According to a third characteristic, the top surface 51A of the first mold resin 51 is located in the same plane as that of the top surfaces 311A of the outer lead portions 311. Therefore, the pressurizing position can be set in a wide range and with a high flexibility in the resin sheet curing process (Step S4 in FIG. 6) and stabler pressing force can be applied.

### Fourth Characteristic

The entirety of the surface of the inner lead portions 313 is covered by the first mold resin 51. As illustrated in FIGS. 4A and 5, the entire surface of the inner lead portions 313 of the first lead terminals 31 is covered by the first mold resin 51. The entirety of the surface of the inner lead portions 313 indicates the entirety of the inner lead portions 313 including the top surface 313A, the bottom surface 313B, and the side surface connecting the top surface 313A and the bottom surface 313B to each other.

Since the entirety of the surface of the inner lead portions 313 of the first lead terminals 31 is covered by the first mold resin 51 according to a fourth characteristic, separation of the first mold resin 51 from the first lead terminals 31 can be suppressed.

### Fifth Characteristic

The side surface 51C of the first mold resin 51 is covered by the second mold resin 52. As illustrated in FIG. 5, the first mold resin 51 has the side surface 51C connecting the bottom surface 51B and the top surface 51A to each other, and at least a part of the side surface 51C is covered by the second mold resin 52. In the example of FIG. 5, the entirety of the surface of the side surface 51C is covered by the second mold resin 52. In the example of FIG. 5, the side surface 51D adjacent to the second lead terminals 32 is also covered by the second mold resin 52.

According to a fifth characteristic, a decrease in the strength of the side surface 51C can be suppressed compared to a configuration in which the entirety of the side surface 51C of the first mold resin 51 is exposed. Generally, a mold resin having a high thermal conductivity is lower in shielding performance than a mold resin having a low thermal conductivity. In a case in which a mold resin that is low in shielding performance constitutes the external surface of the semiconductor device 10, dust or moisture may enter inside the semiconductor device 10, and members sealed therein (parts of the first lead terminals 31 and the second lead terminals 32 arranged inside the semiconductor device 10, the power semiconductor chips 12, the control semiconductor chips 14, and the like) are likely to corrode or fail. In a case in which the thermal conductivity of the first mold resin 51 is greater than that of the second mold resin 52, there is a possibility that the durability of the semiconductor device 10 will be decreased if the first mold resin 51 is exposed on the external surface of the semiconductor device 10. With covering of the side surfaces 51C and 51D of the first mold resin 51 by the second mold resin 52 that is relatively higher in shielding performance as in the fifth characteristic, the durability of the semiconductor device 10 can be increased.

### Sixth Characteristic

The first mold resin 51 is arranged in an area adjacent to the first lead terminals 31 and also in an area adjacent to the second lead terminals 32. As illustrated in FIGS. 4A and 5, the first mold resin 51 is arranged not only in an area adjacent to the first lead terminals 31 as seen from the metallic plates 33, but also in an area adjacent to the second lead terminals 32 as seen from the metallic plates 33. The semiconductor device 10 includes the outer lead portions 321 of the second lead terminals 32 and the control semiconductor chips 14. The outer lead portions 321 of the second lead terminals 32 extend in parallel to the reference plane S, being spaced apart from the reference plane S such that the reference plane S is between the respective outer lead portion 321 and the insulating resin layer 42. The metallic plates 33 are between the outer lead portions 321 of the second lead terminals 32 and the outer lead portions 311 of the first lead terminals 31 in plan view. The control semiconductor chips 14 are adhered to the top surfaces 321A of the associated outer lead portions 321. The top surfaces 321A are surfaces not facing the reference plane S, i.e., surfaces on the opposite side of the bottom surfaces 321B facing the reference plane S. The top surface 51A of the first mold resin 51 is located in the same plane as that of the top surfaces 321A of the outer lead portions 321 of the second lead terminals 32 to which the control semiconductor chips 14 are adhered.

According to a sixth characteristic, the top surface 51A of the first mold resin 51 is located in the same plane as that of the top surfaces 321A of the outer lead portions 321 of the second lead terminals 32 to which the control semiconductor chips 14 are adhered. Therefore, pressing force can be applied from both sides of the metallic plates 33 in the resin sheet curing process (Step S4 in FIG. 6) and stabler pressing force can be provided.

### Seventh Characteristic

The power semiconductor chips 12 are arranged in the opening 510 of the first mold resin 51. As illustrated in FIG. 4B, the first mold resin 51 has the opening 510 extending from the top surface 51A to the bottom surface 51B, the top surfaces 33A of the metallic plates 33 are exposed in the opening 510 adjacent to the bottom surface 51B, and the power semiconductor chips 12 are adhered to, of the top surfaces 33A of the metallic plates 33, parts exposed in the opening 510.

In the first mold resin sealing process at Step S2 in FIG. 6, the opening 510 is formed using the mold cavity 81 having a shape corresponding to the opening 510. Therefore, according to a seventh characteristic, it is possible to ensure places in which the power semiconductor chips 12 are arranged by a simple process. Furthermore, due to provision of the opening 510, a space is formed around the power semiconductor chips 12, thus facilitating work of connecting the wires 38 to the power semiconductor chips 12 (the wire bonding process at Step S5 in FIG. 6).

### Eighth Characteristic

The opening 510 widens upward with an opening at the top larger than an opening at the bottom. As illustrated in FIG. 5, the area (the size of the shape of a cross section) of the opening 510 adjacent to the top surface 51A of the first mold resin 51 is larger than the area (the size of the shape of a cross section) of the opening 510 adjacent to the bottom surface 51B.

According to an eighth characteristic, the wall surfaces (side walls) 51F and 51G between the top surface 51A and the bottom surface 51B of the first mold resin 51 are inclined surfaces spreading out toward the top surface 51A. Therefore, a wide workspace at the time of connecting the wires 38 to the power semiconductor chips 12 can be provided, and it is therefore possible to improve workability while ensuring the contact area between the first mold resin 51 and the insulating resin layer 42. The work area at that time is, for example, a space in which a device forming the wires 38 can move so as not to interfere with the first mold resin 51. Furthermore, the mold cavity 81 can be smoothly removed at the time of shaping of the first mold resin 51.

### Ninth Characteristic

The planar shapes of the first mold resin 51, the heatsink 41, and the insulating resin layer 42 are the same. As illustrated in FIG. 5, the outer peripheral edge (the location of the side surface 51C on the XY plane) of the first mold resin 51, the outer peripheral edge (the location of the side surface 41C on the XY plane) of the heatsink 41, and the outer peripheral edge (the location of the side surface 42C on the XY plane) of the insulating resin layer 42 are aligned in plan view.

According to a ninth characteristic, at the time of stacking the first mold resin 51, the heatsink 41, and the insulating resin layer 42, members that are the same in planar shape, are placed one after another and the formability of the semiconductor device 10 can be enhanced.

### Tenth Characteristic

The side surfaces 33C of the metallic plates 33 are covered by the first mold resin 51. As illustrated in FIG. 4B, the side surfaces 33C of the metallic plates 33 are covered by the first mold resin 51.

Since there is no step between the metallic plates 33 and the first mold resin 51 according to a tenth characteristic, stress concentration caused by the second mold resin 52 can be reduced.

### Eleventh Characteristic

At least a part of the outer peripheral edge of the top surface 33A of the respective metallic plate 33 is covered by the first mold resin 51. As illustrated in FIG. 5, the outer peripheral edge of the top surface 33A of the metallic plate includes a first portion adjacent to the first lead terminal 31 and a second portion on a side opposite the first portion, i.e., the first and second portions are opposed portions of the top surface 33A of the metallic plate 33. At least a part of the first portion of the outer peripheral edge and at least a part of the second portion of the outer peripheral edge are covered by the first mold resin 51.

According to an eleventh characteristic, separation (peeling) of the metallic plates 33 from the insulating resin layer 42 can be prevented.

In FIG. 5, the metallic plates 33 are arranged along the X direction, and portions along the X direction of the outer peripheral edges of the top surfaces 33A of the metallic plates 33 are covered by the first mold resin 51. When the metallic plates 33 are arranged along the X direction, it is preferable that portions along the Y direction of the outer peripheral edges of the top surfaces 33A of the metallic plates 33 not be covered by the first mold resin 51. This is to provide a larger mounting region of the power semiconductor chips 12 on the top surfaces 33A of the metallic plates 33.

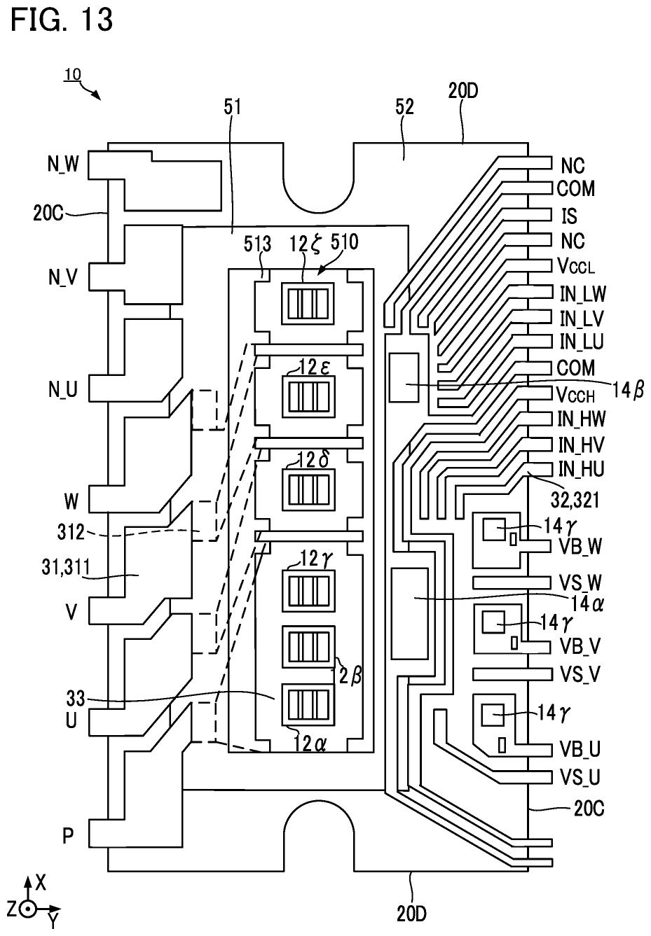

Furthermore, while the entirety of the portions along the X direction of the outer peripheral edges of the top surfaces 33A of the metallic plates 33 along the X direction is covered by the first mold resin 51 in FIG. 5, for example, only a part of the portions along the X direction of the outer peripheral edges may be covered by the first mold resin 51, as illustrated in FIG. 13. In the example of FIG. 13, only four corners of the top surface 33A of each of the metallic plates 33 exposed in a quadrangular shape in the opening 510 are covered by the first mold resin 51 (convex portions 513). In this manner, by covering only a part of the outer peripheral edges of the metallic plates 33 with the first mold resin 51, a larger mounting region of the power semiconductor chips 12 on the top surfaces 33A of the metallic plates 33 can be provided.

### Twelfth Characteristic

The side surface 41C of the heatsink 41 is surrounded by the second mold resin 52. As illustrated in FIG. 5, the side surface 41C of the heatsink 41 is covered by the second mold resin 52.

Since the side surface 41C of the heatsink 41 is covered by the second mold resin 52 according to a twelfth characteristic, a decrease in the strength of the heatsink 41 can be suppressed.

### Thirteenth Characteristic

The side surface 42C of the insulating resin layer 42 is surrounded by the second mold resin 52. As illustrated in FIG. 5, the side surface 42C of the insulating resin layer 42 is covered by the second mold resin 52.

Since the side surface 42C of the insulating resin layer 42 is covered by the second mold resin 52 according to a thirteenth characteristic, a decrease in the strength of the insulating resin layer 42 can be suppressed.

### Fourteenth Characteristic

The semiconductor device 10 includes power semiconductor chips 12 (metallic plates 33). As illustrated in FIG. 4B, the metallic plates 33 are in contact with the top surface 42A of the insulating resin layer 42, the first lead terminals 31 and the second lead terminals 32 each are provided to correspond to a respective metallic plate 33, and the first mold resin 51 is formed as a single piece across the metallic plates 33.

Since the first mold resin 51 is integrally shaped in the semiconductor device 10 having the metallic plates 33 according to a fourteenth characteristic, the shaping process can be simplified as compared to a case in which the first mold resin 51 is shaped individually for each of the metallic plates 33.

### Fifteenth Characteristic

The thermal conductivity of the first mold resin 51 is higher than that of the second mold resin 52. As described above, the thermal conductivity of the first mold resin 51 is higher than that of the second mold resin 52.

According to a fifteenth characteristic, in a course in which heat produced by the power semiconductor chips 12 transfers through the metallic plates 33 and the first lead terminals 31 (the inner lead portions 313 and parts of the outer lead portions 311 connecting to the inner lead portions 313), the heat is likely to transfer also to the first mold resin 51 that seals the metallic plates 33 and the first lead terminals 31. This can prevent the heat produced by the power semiconductor chips 12 from transferring through the first lead terminals 31 to other members to which the first lead terminals 31 are connected. In particular, since the first mold resin 51 is arranged at parts being in contact with the insulating resin layer 42 adhered to the heatsink 41, the amount of heat transferred to the heatsink 41 is increased and the cooling effect on the power semiconductor chips 12 can be enhanced as compared to a case in which these parts are covered by the second mold resin 52.

Generally, a mold resin having a high thermal conductivity is more expensive than a standard type of mold resin (having a standard thermal conductivity). In the semiconductor device 10, the first mold resin 51 is used in a part near the power semiconductor chips 12 and the second mold resin 52 is used in other parts. Therefore, the cooling effect on the power semiconductor chips 12 can be enhanced while an increase in the manufacturing cost of the semiconductor device 10 is suppressed.

### Sixteenth Characteristic

The entirety of the semiconductor device 10 is sealed by the second mold resin 52. As illustrated in FIG. 5, the constituent members of the semiconductor device 10 are all covered by the second mold resin 52, except for a part of the heatsink 41 and parts of the first lead terminals 31 (parts of the outer lead portions 311 and the tip portions 312).

Since the constituent members except for the part of the heatsink 41 and the parts of the first lead terminals 31 are covered by the second mold resin 52 according to a sixteenth characteristic, the main body portion 20 of the semiconductor device 10 can be formed of the second mold resin 52. Furthermore, since the surface of the semiconductor device 10 is formed of a single mold resin, the durability of the semiconductor device 10 can be improved as compared to a case in which plural types of mold resins are exposed on the external surface. Specifically, for example, in a configuration in which a boundary between plural types of mold resins having different properties is exposed on the surface of the main body portion 20, there is a possibility that separation occurs therebetween from the boundary. In contrast thereto, there is no boundary surface on a surface continuously formed of a signal mold resin, and therefore, the durability of the semiconductor device 10 can be improved.

In particular, a mold resin having a high thermal conductivity is lower in shielding performance than a (standard type of) mold resin having a low heat transfer property and has a possibility of having reduced strength when exposed on the outer peripheral edge. Accordingly, the strength of the semiconductor device 10 can be enhanced by sealing the entirety of the semiconductor device 10 with the second mold resin 52 without the first mold resin 51 exposed.

### Seventeenth Characteristic

The bottom surface 41B of the heatsink 41 is exposed on the surface of the semiconductor device 10. As illustrated in FIG. 5, a surface on a side of the heatsink 41 opposite to a surface on which the insulating resin layer 42 is formed, i.e., the bottom surface 41B, is exposed on the surface of the semiconductor device 10. As described above, the bottom surface 41B of the heatsink 41 constitutes the bottom surface 20B of the main body portion 20 along with the second mold resin 52.

According to a seventeenth characteristic, the bottom surface 41B of the heatsink 41 is entirely exposed to an outside of the semiconductor device 10. Therefore, it is possible to easily release heat produced by the power semiconductor chips 12 to the outside via the heatsink 41, and the cooling performance of the semiconductor device 10 can be improved.

### Eighteenth Characteristic

The bottom surface 41B of the heatsink 41 and the second mold resin 52 are in the same plane. As illustrated in FIG. 5, the second mold resin 52 has a surface located in the same plane as that of the bottom surface 41B of the heatsink 41 exposed to an outside of the semiconductor device 10.

The second mold resin 52 has a surface located in the same plane as that of the bottom surface 41B (a surface on the opposite side to the insulating resin layer 42) of the heatsink 41 according to an eighteenth characteristic. Therefore, when the semiconductor device 10 is placed with this surface down, the attitude is stabilized, and the side surface 41C of the heatsink 41 can be protected.

### Nineteenth Characteristic

As illustrated in FIG. 6, a manufacturing method for the semiconductor device 10 includes the first mold resin sealing process (first process) of covering parts of the metallic plates 33 and parts of the first lead terminals 31 with the first mold resin 51, the resin sheet curing process (second process) of bringing the bottom surfaces 33B of the metallic plates 33 and the bottom surface 51B of the first mold resin 51 into contact with the resin sheet 420 and curing the resin sheet 420 to form the insulating resin layer 42, and the second mold resin sealing process (third process) of covering the metallic plates 33, the power semiconductor chips 12, and parts of the first lead terminals 31 with the second mold resin 52.

According to a nineteenth characteristic, after the parts of the metallic plates 33 and the parts of the first lead terminals 31 are covered with the first mold resin 51, the bottom surfaces 33B of the metallic plates 33 and the bottom surface 51B of the first mold resin 51 are brought into contact with the resin sheet 420, and the resin sheet 420 is cured to form the insulating resin layer 42. Since the bottom surfaces 33B of the metallic plates 33 and the bottom surface 51B of the first mold resin 51 are located in the same plane, the bottom surface 51B of the first mold resin 51, in addition to the bottom surface 33B of the metallic plates 33, is brought into contact with the surface of the resin sheet 420 when the metallic plates 33 are brought into contact with the resin sheet 420. Accordingly, the contact area between the resin sheet 420 and other members (the metallic plates 33 and the first mold resin 51) is increased and the pressing force at the time of the contact can be distributed as compared to a case in which only the metallic plates 33 are brought into contact with the resin sheet 420.

In particular, as explained with reference to Step S4 in FIG. 6, the insulating resin layer 42 is formed by curing the resin sheet 420 in a half-cured state by pressurizing and heating the resin sheet 420. At that time, if the end portions of the metallic plates 33 are brought into contact with the resin sheet 420, the pressing force is concentrated on parts of the resin sheet 420 being in contact with the end portions, and these parts may be deformed. According to the manufacturing method for the nineteenth characteristic, the bottom surface 51B of the first mold resin 51 located in the same plane as that of the bottom surfaces 33B of the metallic plates 33 extends to a location overlapping with the line of the outer peripheral edge of the insulating resin layer 42 (the resin sheet 420). Therefore, the end portions of the metallic plates 33 are not positioned on the resin sheet 420, and deformation at the time of curing the resin sheet 420 can be prevented. Although the outer peripheral end portions of the metallic plates 33 are places at which the electric field is concentrated in the practical operating state, as described above, defects in the insulating resin layer 42 in the vicinity can be suppressed, and the reliability of the semiconductor device 10 can be improved.

### Modifications

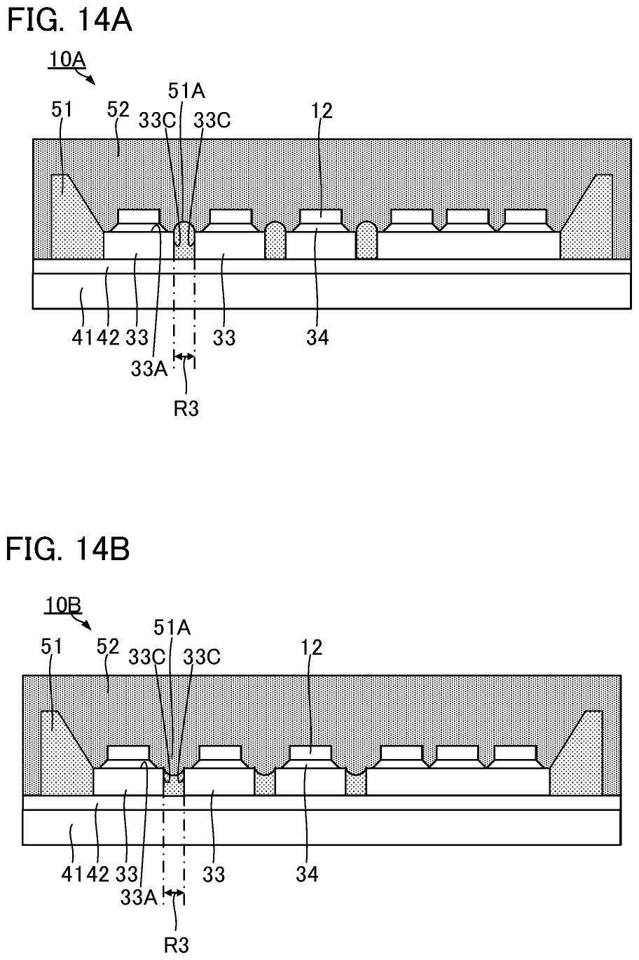

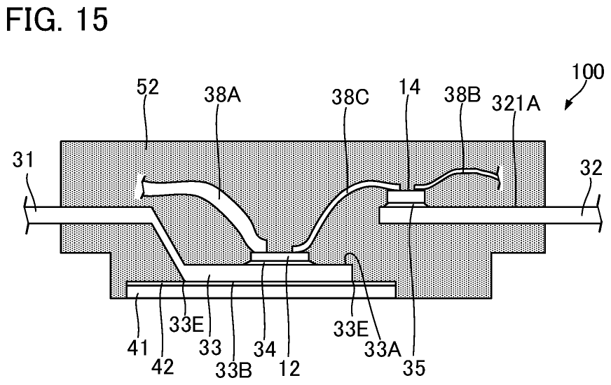

FIG. 14A is a sectional view along the X direction of a semiconductor device 10A according to a modification, and FIG. 14B is a sectional view along the X direction of a semiconductor device 10B according to the modification. In the configurations of the semiconductor devices 10A and 10B, configurations identical to those of the semiconductor device 10 according to the embodiment are denoted by like reference signs, and detailed descriptions thereof are omitted.

In the semiconductor device 10A illustrated in FIG. 14A, a plurality of metallic plates 33 are arranged on the insulating resin layer 42 placed on the heatsink 41, similarly to the semiconductor device 10. The first mold resin 51 is arranged on a region between adjacent ones of the metallic plates 33, more specifically, a region R3 sandwiched between the side surfaces 33C of adjacent ones of the metallic plates 33. In the semiconductor device 10 according to the embodiment, the top surface 51A of the first mold resin 51 arranged in the regions between adjacent ones of the metallic plates 33 is located in the same plane as that of the top surfaces 33A of the metallic plates 33. In contrast thereto, in the semiconductor device 10A, the top surface 51A of the first mold resin 51 arranged in regions between adjacent ones of the metallic plates 33 protrudes with respect to the top surfaces 33A of the metallic plates 33. In the semiconductor device 10B illustrated in FIG. 14B, the top surface 51A of the first mold resin 51 arranged in regions between adjacent ones of the metallic plates 33 is dented with respect to the top surfaces 33A of the metallic plates 33.

That is, in the semiconductor devices 10A and 10B according to the modification, the regions sandwiched between the side surfaces 33C of adjacent ones of the metallic plates 33 are covered by the first mold resin 51. The surface of the first mold resin 51 in the regions sandwiched by the side surfaces 33C is dented or protruded with respect to the top surfaces 33A of the metallic plates 33.

According to the semiconductor devices 10A and 10B of the modifications, the creepage distance between the metallic plates 33 is elongated, and the insulation property can be enhanced as compared to a case in which the top surface 51A of the first mold resin 51 between the metallic plates 33 is a flat surface.

### DESCRIPTION OF REFERENCE SIGNS

10 . . . semiconductor device, 12 (12α to 12ξ) . . . power semiconductor chip, 14 (14α to 14γ) . . . control semiconductor chip, 20 . . . main body portion, 31 . . . first lead terminal, 32 . . . second lead terminal, 33 . . . metallic plate, 34 . . . adhesion material, 35 . . . adhesion material, 38 (38A to 38C) . . . wire, 41 . . . heatsink, 42 . . . insulating resin layer, 51 . . . first mold resin, 510 . . . opening, 52 . . . second mold resin, 81, 82 . . . mold cavity, 83 . . . plate-like member, 311, 321 . . . outer lead portion, 312, 322 . . . tip portion, 313 . . . inner lead portion, 420 . . . resin sheet.

What is claimed is:

1. A semiconductor device comprising:
a heatsink;
an insulating resin layer, a surface of which includes a first region and a second region different from the first region, the insulating resin layer being formed on the heatsink;
a metallic plate including a first surface and a second surface opposite the first surface, with the first surface in contact with the first region of the surface of the insulating resin layer;
a first semiconductor chip adhered to the second surface;
a first lead terminal connected to the metallic plate;
a first mold resin covering a part of the metallic plate and a part of the first lead terminal; and
a second mold resin formed of a resin material with a different property from that of the first mold resin, the second mold resin covering another part of the metallic plate, the first semiconductor chip, and another part of the first lead terminal,
wherein:
the first mold resin includes a third surface located in a same plane as that of the first surface of the metallic plate, the third surface extending from an outer peripheral edge of the metallic plate to an outer peripheral edge of the insulating resin layer or outside thereof in plan view, and
the third surface is in contact with the second region on the surface of the insulating resin layer.

2. The semiconductor device according to claim 1, wherein:
the first mold resin includes a fourth surface opposite the third surface, and
the fourth surface is parallel to the third surface.

3. The semiconductor device according to claim 2, wherein
the first lead terminal includes:
a first portion extending in parallel to a reference plane including the second surface of the metallic surface, the first portion being spaced apart from the reference plane such that the reference plane is between the first portion and the insulating resin layer; and
a second portion that joins the first portion and the metallic plate together, and
the fourth surface of the first mold resin is located in a same plane as a surface of the first portion, the surface of the first portion not facing the reference plane.

4. The semiconductor device according to claim 3, wherein an entirety of a surface of the second portion of the first lead terminal is covered by the first mold resin.

5. The semiconductor device according to claim 2, wherein:
the first mold resin has a fifth surface connecting the third surface and the fourth surface to each other, and
at least a part of the fifth surface is covered by the second mold resin.

6. The semiconductor device according to claim 2, further comprising:
a second lead terminal extending in parallel to a reference plane including the second surface of the metallic plate, the second lead terminal being spaced apart from the reference plane such that the reference plane is between the second lead terminal and the insulating resin layer; and
a second semiconductor chip adhered to a surface of the second lead terminal, the surface not facing the reference plane,
wherein:
the metallic plate is between the second lead terminal and the first portion of the first lead terminal in plan view, and
the fourth surface of the first mold resin is located in a same plane as the surface of the second lead terminal, to which surface the second semiconductor chip is adhered.

7. The semiconductor device according to claim 6, wherein:
the first mold resin has an opening extending from the fourth surface to the third surface of the first mold resin,
a part of the second surface of the metallic plate is exposed adjacent to the third surface in the opening, and
the first semiconductor chip is adhered to, of the second surface of the metallic plate, the part exposed in the opening.

8. The semiconductor device according to claim 7, wherein an area of the opening adjacent to the fourth surface of the first mold resin is larger than an area of the opening adjacent to the third surface of the first mold resin.

9. The semiconductor device according to claim 1, wherein an outer peripheral edge of the first mold resin, an outer peripheral edge of the heatsink, and an outer peripheral edge of the insulating resin layer are aligned in plan view.

10. The semiconductor device according to claim 1, wherein an outer peripheral surface of the metallic plate is covered by the first mold resin.

11. The semiconductor device according to claim 1, wherein:
an outer peripheral edge of the second surface of the metallic plate includes a first portion adjacent to the first lead terminal and a second portion on a side opposite the first portion, and
at least a part of the first portion of the outer peripheral edge of the second surface of the metallic plate and at least a part of the second portion of the outer peripheral edge of the second surface of the metallic plate are covered by the first mold resin.

12. The semiconductor device according to claim 1, wherein an outer peripheral surface of the heatsink is covered by the second mold resin.

13. The semiconductor device according to claim 1, wherein an outer peripheral surface of the insulating resin layer is covered by the second mold resin.

14. The semiconductor device according to claim 1, wherein:
a plurality of metallic plates are in contact with a surface of the insulating resin layer,
a plurality of first lead terminals are each provided to correspond to a respective metallic plate, and
the first mold resin is formed as a single piece across the plurality of metallic plates.

15. The semiconductor device according to claim 14, wherein:
a region sandwiched between outer peripheral surfaces of adjacent ones of the plurality of metallic plates is covered by the first mold resin, and
a surface of the first mold resin in the region sandwiched by the outer peripheral surfaces is dented or protruded with respect to the second surface of the metallic plates.

16. The semiconductor device according to claim 1, wherein a thermal conductivity of the first mold resin is higher than that of the second mold resin.

17. The semiconductor device according to claim 1, wherein the heatsink, the insulating resin layer, the metallic plate, the first semiconductor chip, the first lead terminal, and the first mold resin are all covered by the second mold resin except for a part of the heatsink and a part of the first lead terminal.

18. The semiconductor device according to claim 1, wherein a surface on a side of the heatsink opposite a surface on which the insulating resin layer is formed is exposed on a surface of the semiconductor device.

19. The semiconductor device according to claim 18, wherein the second mold resin has a surface located in a same plane as the surface of the heatsink exposed outside the semiconductor device.

20. A manufacturing method for a semiconductor device comprising:
a first process;
a second process; and
a third process,
wherein the semiconductor device includes:
a heatsink;
an insulating resin layer, a surface of which includes a first region and a second region different from the first region, the insulating resin layer being formed on the heatsink;
a metallic plate including a first surface and a second surface opposite the first surface, with the first surface in contact with the first region of the surface of the insulating resin layer;
a first semiconductor chip adhered to the second surface;
a first lead terminal connected to the metallic plate;
a first mold resin covering a part of the metallic plate and a part of the first lead terminal; and
a second mold resin formed of a resin material with a different property from that of the first mold resin, the second mold resin covering another part of the metallic plate, the first semiconductor chip, and another part of the first lead terminal,
wherein:
the first mold resin includes a third surface located in a same plane as that of the first surface of the metallic plate, the third surface extending from an outer peripheral edge of the metallic plate to an outer peripheral edge of the insulating resin layer or outside thereof in plan view,
the third surface is in contact with the second region on the surface of the insulating resin layer,
the first process covers a part of the metallic plate and a part of the first lead terminal with the first mold resin,
the second process forms the insulating resin layer by bringing the first surface of the metallic plate and the third surface of the first mold resin into contact with a resin sheet and curing the resin sheet, and
the third process covers the metallic plate, the first semiconductor chip, and a part of the first lead terminal with the second mold resin.
